(19) United States
(12) Patent Application Publication
(10) Pub. No.: US 2025/0354253 A1
(43) Pub. Date: Nov. 20, 2025

(54) METHOD FOR PRODUCING A MIRROR ASSEMBLY, AND COATING SYSTEM

(71) Applicant: Carl Zeiss SMT GmbH, Oberkochen (DE)

(72) Inventors: Florian AHREND, Heidenheim (DE); Thomas SCHICKETANZ, Aalen (DE)

(21) Appl. No.: 19/281,872

(22) Filed: Jul. 28, 2025

Related U.S. Application Data
(63) Continuation of application No. PCT/EP2023/082983, filed on Nov. 24, 2023.

(30) Foreign Application Priority Data
Jan. 26, 2023 (DE) 10 2023 200 603.0

(51) Int. Cl. C23C 14/50; C23C 14/34

(52) U.S. Cl. CPC C23C 14/50; C23C 14/34

(57) ABSTRACT

A method for producing a mirror assembly, as well as a coating system. The mirror assembly is, for instance, a mirror assembly for microlithography, e.g. for a microlithographic projection exposure system. In the method, a coating process of a plurality of mirror substrates (106, 206, 306, 406) is carried out in a coating system, wherein coating material is supplied by at least one target (103, 203, 303, 403, 503) for the deposition of at least one respective layer system on each of the mirror substrates (106, 206, 306, 406). The mirror substrates (106, 206, 306, 406) are each tilted by a tilt angle individually adjustable for each mirror substrate. This enables the respective thickness profile generated in the coating process to be adjusted individually.

### CROSS REFERENCE TO RELATED APPLICATIONS

This is a Continuation of International Application PCT/EP2023/082983 which has an international filing date of Nov. 24, 2023, and the disclosure of which is incorporated in its entirety into the present Continuation by reference. This Continuation also claims foreign priority under 35 U.S.C. § 119 (a)-(d) to and also incorporates by reference, in its entirety, German Patent Application DE 10 2023 200 603.0 filed on Jan. 26, 2023.

### FIELD OF THE INVENTION

According to one formulation, the invention relates to a method for producing a mirror arrangement and to a coating apparatus. In particular, the mirror arrangement may be a microlithographic mirror arrangement, e.g. for a microlithographic projection exposure apparatus.

### BACKGROUND

Microlithography is used for producing microstructured components, such as integrated circuits or LCDs. The microlithography process is performed in what is known as a projection exposure apparatus, which comprises an illumination device and a projection lens. The image of a mask (=reticle) illuminated with the illumination device is in this case projected with the projection lens onto a substrate (e.g. a silicon wafer) coated with a light-sensitive layer (photoresist) and arranged in the image plane of the projection lens, in order to transfer the mask structure to the light-sensitive coating on the substrate.

In projection lenses designed for the extreme ultraviolet (EUV) range, e.g. at wavelengths of e.g. approximately 13 nm or approximately 7 nm, owing to the lack of availability of suitable light-transmissive refractive materials, mirrors are used as optical components for the imaging process.

The use of mirror arrangements constructed from a plurality of individual mirrors (e.g. in the form of faceted mirrors or pupil facet mirrors) for flexibly setting different illumination angle distributions is known not only in the illumination device of a microlithographic projection exposure apparatus designed for EUV operation but also in microlithographic projection exposure apparatuses designed for operation at wavelengths in the deep ultraviolet (DUV) range (e.g. at wavelengths of approx. 248 nm or approx. 193 nm). These individual mirrors may be designed to be settable or tiltable independently of one another through flexures in each case and may in turn be constructed as blocks of individual micromirrors in the form of microelectromechanical systems (so-called “MEMS mirror”).

For example, magnetron coating apparatuses are used for mirror production. Such a magnetron coating apparatus typically comprises a plurality of magnetrons, which are each assigned a target with a corresponding coating material. To coat a substrate, the respective substrate (this is understood to mean the carrier for the layer to be applied in the coating method or the layer system to be applied) is guided over the coating positions that face the respective targets or magnetrons.

A problem that arises in practice is that coating errors, in particular in the form of coating thickness errors or else on account of adjustment errors in the respective coating mount, are generally unavoidable in the real coating process, wherein an unwanted drift (i.e. a temporal variation of the layer thicknesses set in the coating process, both within a layer structure and over a plurality of mirrors produced in succession) may also occur. These problems are particularly severe in the case of EUV mirrors with periodically constructed multilayer systems in particular because the respective layer thickness errors propagate systematically in the layer thickness profile, with the consequence that already small deviations of the individual layers from the respective target layer thickness lead to significant impairments of the overall performance of the optical system.

In addition to the requirement of correcting the aforementioned effects, there is also a need in practice to improve the reflectivity and ultimately the overall performance of the optical system by a flexible targeted selection of the layer properties.

In relation to the prior art, reference is made merely by way of example to DE 10 2016 201 564 A1, DE 10 2015 225 535 A1, DE 10 2015 217 603 A1, DE 10 2012 215 359 A1, DE 10 2012 204 833 A1, WO 2022/008102 A1 and U.S. Pat. No. 10,423,073 B2.

### SUMMARY

Against the aforementioned background, a problem addressed by aspects of the present invention is that of providing a method for producing a mirror arrangement and a coating apparatus such that flexible manipulation of layer properties is made possible, e.g. for correcting layer thickness errors and/or adjustment errors.

This problem is addressed by the features recited in the independent patent claims.

A method according to one formulation of the invention for producing a mirror arrangement having a plurality of mirror elements, in particular for microlithography, includes, in a coating process performed in a coating apparatus, coating material from at least one target being supplied to a plurality of mirror substrates for the purpose of depositing a respective layer system on each of the mirror substrates.

The method is characterized in that the mirror substrates are each tilted about a tilt angle that can be set individually for each mirror substrate, for the purpose of individually setting the respective thickness profile created in the coating process. This tilting of the mirror substrates in the coating process or in the coating apparatus may be implemented “in situ” in particular.

In this context, a thickness profile within the meaning of the present application is understood to be a lateral thickness profile of a layer or of a layer system. In principle, the thickness profile may be a constant thickness profile or else a thickness profile that varies over the optically effective surface of the mirror element. In particular, the layer system may contain a reflection layer system and optionally further functional layers as well.

In this context, the formulation within the meaning of the present application whereby the mirror elements “are each tilted about a tilt angle that can be set individually for each mirror substrate” is understood to mean that this comprises both embodiments in which multiple or all mirror elements are tilted by the same tilt angle in each case and embodiments in which multiple or all mirror elements are tilted by tilt angles that differ from one another. Moreover, the tilt angles in each case set for the individual mirrors may vary over time or else be constant over time, depending on the embodiment. Furthermore, the tilt angle set in each case for one or more mirror elements may have a value not equal to zero or else the value of zero.

Starting point for one aspect of the invention is the recognition that a change in the deposition angle or vapor deposition angle in the coating process is able to influence the layer thickness profile and, moreover, further layer properties (e.g. roughness, crystallinity, layer stress, etc.) as well. In this context, one aspect of the invention in particular makes use of the principle of controlled modification of these properties by tilting the respective mirror substrates. In the event of a potential deterioration in certain parameters or layer properties, it is possible to make adaptations (known per se) to further process conditions in order to counteract this. For example, in the event of a comparatively significant tilt leading in certain systems to an unwanted increase in roughness, the latter may be influenced or reduced by optimizing e.g. the operating pressure.

In particular, within the scope of producing a mirror arrangement having a plurality of mirror elements, one aspect of the invention makes use of the concept of implementing, through active control of the individual mirror substrates in the coating process, an individual setting of a respective tilt angle for each of the mirror substrates before or during the deposition of the respective layer systems on the individual mirror substrates, and thus of influencing, in a targeted manner, not only the respective thickness profile in particular but optionally also further layer properties via the change in the vapor deposition angle (and hence in turn in the amount of coating material deposited on the mirror substrate) that accompanies this tilting. As a result of individually setting a respective tilt angle for each of the mirror substrates, an individual thickness factor for the coating process may be assigned to each mirror substrate to be coated or to each fabricated mirror element.

In the process, the respective tilting of the individual mirror substrates may also be varied dynamically in the coating process, with it also being possible in particular to create thickness profiles in which variations in the layer thickness or optionally in further layer properties are also present within one and the same mirror element (and not only at the respective boundaries of adjacent mirror elements). In other words, in particular, it is also possible according to this aspect of the invention to produce mirror arrangements in which the respective boundaries between regions of different layer properties do not correspond to the boundaries between adjacent mirror elements.

Through the above-described flexible and individual tilting of individual mirror substrates, an approach according to the invention differs in particular from conventional approaches, in which, merely for different blocks of mirror substrates, introduction in the process chamber is preceded by static setting of a certain tilt angle, in each case on a group-by-group basis, and in which the coating process is subsequently performed after the introduction of the respective blocks in the process chamber in order to ultimately assemble the corresponding blocks to form the mirror arrangement.

According to this aspect of the invention, particular flexibility as regards the configuration of the mirror arrangement is also achieved inasmuch as the individual tilting of a mirror substrate on the one hand sets a modified vapor deposition angle (and hence a different mean thickness factor during the coating in comparison with a respective adjacent mirror substrate) and on the other hand also modifies the layer thickness profile created in the coating process over the relevant mirror substrate itself. In this case, depending on the respective specific application scenario, the effect mentioned last (i.e. a locally varying layer thickness profile) may optionally also be wanted or be used to compensate for unwanted effects or aberrations in the respective optical system.

According to an embodiment, tilting is implemented such that a systematic coating error of the coating apparatus is at least partially corrected via the thickness profiles created for the plurality of mirror substrates.

According to an embodiment, tilting is implemented such that an adjustment error of the mirror substrates in the coating apparatus is at least partially corrected via the thickness profiles created for the plurality of mirror substrates.

According to an embodiment, in each case different thickness profiles are created for the plurality of mirror substrates.

According to an embodiment, tilting is implemented such that respective constant thickness profiles are created for the individual mirror substrates.

According to an embodiment, modifying a mean deposition angle in the coating process varies at least one further layer property, in particular roughness, crystallinity or layer stress, in addition to the layer thickness profile.

According to an embodiment, the mirror substrates are moved along a predetermined trajectory relative to the target in the coating process.

According to an embodiment, the tilting of the individual mirror substrates is in each case varied during a single pass over the trajectory.

According to an embodiment, this variation is implemented such that the respective mirror substrate is tilted in the direction of the target during the entire pass over the trajectory or tilted away from the target during the entire pass over the trajectory.

According to an embodiment, the mirror substrates are rotated during the coating process, with the tilting being implemented on the basis of the respective rotation angle of this rotation.

According to an embodiment, the tilting is implemented such that gaps located between adjacent mirror substrates are at least partially shadowed in the coating process as a consequence of the tilting.

According to an embodiment, the supply of coating material by the at least one target is implemented with a time-varying rate. In particular, the supply rate of coating material (“sputtering rate”) may be reduced in a scenario in which depending on the rotational position of the coating mount a shadowing of gaps situated between adjacent mirror substrates is unsuccessful, in order to avoid a contamination with coating material of mechanical components situated behind the gaps.

In embodiments, the trajectory of the coating mount may also be designed such that the mirror substrates are not situated perpendicular over the target at any point during the coating process.

Moreover, in embodiments, a rotational movement may optionally be implemented about only a single (spin) axis of rotation in particular.

Moreover, in embodiments of the invention, the effect of the tilting of the mirror substrates may also be amplified in the coating process by virtue of using a radial dependence of the deposited layer thickness. In this context, it is possible to exploit the circumstances that the amount of coating material deposited is also dependent on the position of the mirror substrate on the coating mount. In the case of comparatively large mounting radii (i.e. a radially further out position on the coating mount), the substrate traverses over the material source at the edge, where the distribution of layer-forming particles is inhomogeneous. At this position, comparatively more coating material comes from the target center than from the edge of the target. Tilting the substrate toward the target center favors the angle of incidence of the stronger particle flux while that of the weaker particle flux is disadvantaged (and vice versa). As a result, this once again amplifies the angle dependence of the resultant layer thickness in the coating process—i.e. the “layer thickness increase” realized in the inventive coating process—on the order of a few percent in relation to the layer thickness.

According to an embodiment, the mirror arrangement is designed for an operating wavelength of less than 30 nm, in particular less than 15 nm.

Aspects of the invention also relate to a mirror arrangement, in particular a microlithographic mirror arrangement, which is produced using a method having the features described above.

According to a further aspect, the invention also relates to a coating apparatus for producing a mirror arrangement, in particular a microlithographic mirror arrangement, having a process chamber, wherein the following are arranged in this process chamber:
at least one target for providing coating material;
a coating mount for holding a plurality of mirror substrates;
a first drive unit for performing a translational movement of the coating mount;
a second drive unit for performing a rotational movement of the coating mount; and
a third drive unit for individually settable tilting of the mirror substrates during the coating process.

According to yet another aspect, the invention furthermore relates to a microlithographic projection exposure apparatus comprising an illumination device and a projection lens, wherein the illumination device, during the operation of the projection exposure apparatus, illuminates a mask situated in an object plane of the projection lens, and the projection lens images structures on mask onto a light-sensitive layer situated in an image plane of the projection lens, wherein the projection exposure apparatus comprises at least one mirror arrangement that was produced using a method having the above-described features.

Further configurations according to the invention will be apparent from the description and the dependent claims.

These aspects of the invention will be explained in detail below on the basis of exemplary embodiments illustrated in the appended figures.

### BRIEF DESCRIPTION OF THE DRAWINGS

In the figures:

FIG. 1 shows a schematic illustration of a possible structure of an inventive coating apparatus;

FIGS. 2A-5B show schematic illustrations for explaining exemplary embodiments of an inventive method, wherein FIGS. 2A, 2B and 2C show mirror substrate trajectories in a non-tilted state, a constant-tilted state and a varied-tilted state, respectively; FIGS. 3A and 3B show mirror substrate trajectories in two respective positions during rotational movement of a coating mount; FIGS. 4A and 4B show non-tilted and tilted mirror substrates, respectively, during a coating process; and FIGS. 5A and 5B show a coating mount in two respective rotational positions; and

FIG. 6 shows a schematic illustration of a projection exposure apparatus designed for operation in the EUV wavelength range.

### DETAILED DESCRIPTION

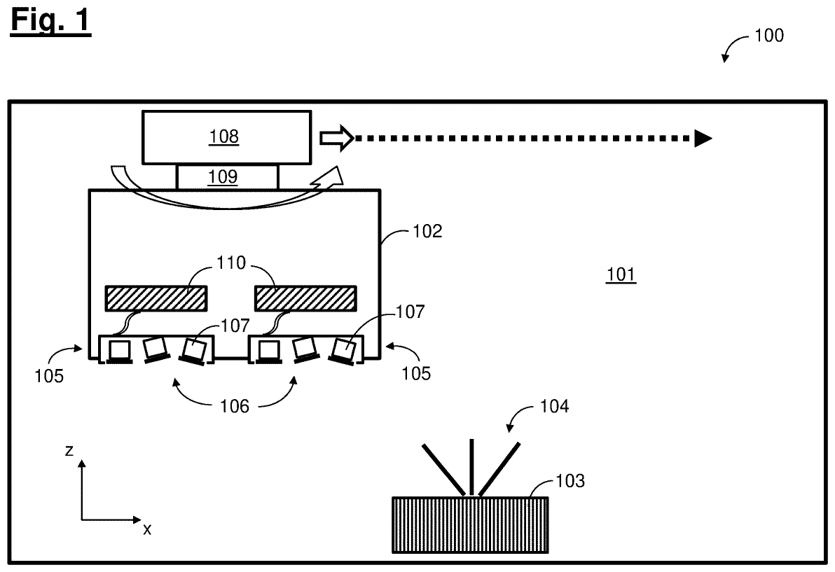

FIG. 1 initially shows a schematic illustration of a feasible structure of a coating apparatus 100 according to one aspect of the invention. Here, a coating mount 102 for holding a plurality of mirror substrates 106 and at least one target 103 for providing coating material 104 are arranged in a process chamber 101 (to which a vacuum pump, not illustrated here, is connected). As indicated in FIG. 1 (without the invention being restricted thereto, however), a plurality of mirror substrates 106 or the ultimately fabricated mirror elements may in each case be grouped into individual blocks 105. To deposit a respective layer system on each of the mirror substrates, the coating mount 102 carrying the mirror substrates 106 is guided over the at least one target 103 along a predetermined trajectory. In the process, the coating mount 102 carries out a translational movement brought about with a first drive unit 108 and optionally also a rotational movement brought about with a second drive unit 109. In addition to the first and second drive units, the coating apparatus 100 according to this aspect of the invention comprises a third drive unit 110 for individually settable tilting of the mirror substrate 106 during the coating process. Mechanical components or joints assigned to the mirror substrates 106 are denoted by “107”.

Below, the assumption is made that in order to produce a mirror arrangement (which may be designed for operation in the EUV or else DUV wavelength range), a respective desired thickness profile of the layer structure (including reflection layer system and possible functional layers) created on the respective mirror substrate should be created for the individual mirror elements of the mirror arrangement.

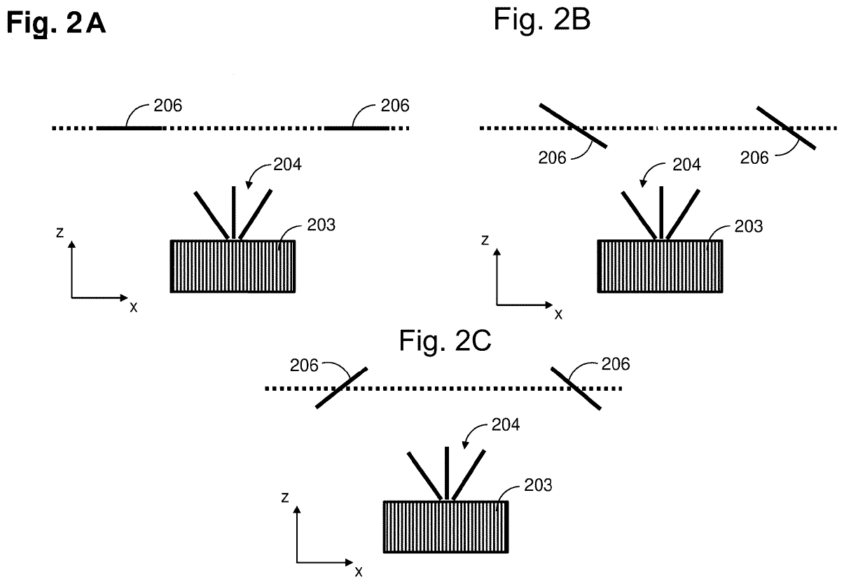

Hereinafter, exemplary embodiments of an inventive method are explained using schematic representations with reference to the schematic diagrams in FIGS. 2A-5B. What is common to these embodiments is that respective mirror substrates are tilted with a respective individually settable tilt angle (or independently of one another) for individual setting of the respective thickness profile created in a coating process (e.g. performed in the coating apparatus of FIG. 1). In this case, electrical power supply required for tilting may be provided on part of the coating mount, wherein rechargeable batteries may also be used.

FIGS. 2A-2C each indicate a predetermined trajectory of a mirror substrate 206 relative to a target 203, with “204” denoting the coating material supplied to the mirror substrate 206 by the target 203. Purely by way of example (and without the invention being restricted thereto), the dimensions of the individual mirror substrates 206 could be 1 mm*1 mm. In this context, FIG. 2A illustrates the trajectory of the mirror substrate 206 in the non-tilted state, and FIG. 2B illustrates the trajectory in the tilted state with a tilt angle that is constant over time. FIG. 2C illustrates the trajectory, likewise in the tilted state, wherein in contrast to FIG. 2B, the tilting of the mirror substrate 206 is in each case varied during a single pass over the trajectory according to FIG. 2C. In particular, this single change in the tilt angle of the mirror substrate 206 may be implemented when the position situated centrally over the target 203 is reached and implemented such that the mirror substrate 206 is tilted toward the target 203 on average. In further embodiments, the tilt angle may also be changed such that the mirror substrate 206 is tilted away from the target 203 on average. Each of the two scenarios makes it possible to avoid the break in the symmetry that otherwise occurs during the movement of the mirror substrate 206 relative to the target. Hence, it is possible to realize a constant thickness profile during the coating of the relevant mirror substrate 206.

Considered quantitatively, if perpendicular coating is used as a starting point, a change in the vapor deposition angle of 100 mrad (corresponding to approximately 6°) caused by the inventive tilting leads to a variation in the created layer thickness of approximately 0.5%, on account of cos (0.1)≅0.995. On account of the nonlinear relationship by way of the cosine function, the effect on the created layer thickness obtained by changing the vapor deposition angle increases significantly at relatively large vapor deposition angles: A change in the mean angle of incidence of layer-forming particles by 10° already brings about a variation in the created layer thickness of approximately 2.2%, whereas a change in the mean angle of incidence by 30° already leads to a variation in the created layer thickness of approximately 6.2%.

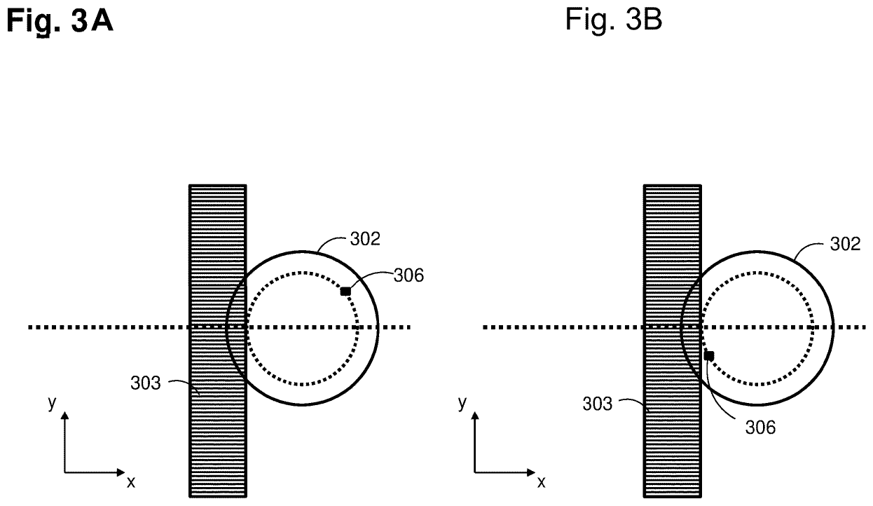

Further embodiments may take account of the fact that the mirror substrates are rotated during the coating process, even in the event of the inventive tilting of the mirror substrates, wherein the tilting may be implemented in a manner dependent on the respective rotation angle of this rotation in particular. The schematic illustrations of FIGS. 3A-3B illustrate this rotational movement in a plan view. Dynamic tilting of a mirror substrate 306 permits the mirror substrate to be always (i.e. over the entire rotational movement in particular) aligned toward the target 303 (or else alternatively to be also directed away from the target 303, for instance should a thinner coating be desired). In this context, control of the tilting of the mirror substrate must be implemented more quickly than the rotational speed of the rotational movement of the coating mount 302 that carries the mirror substrates 306.

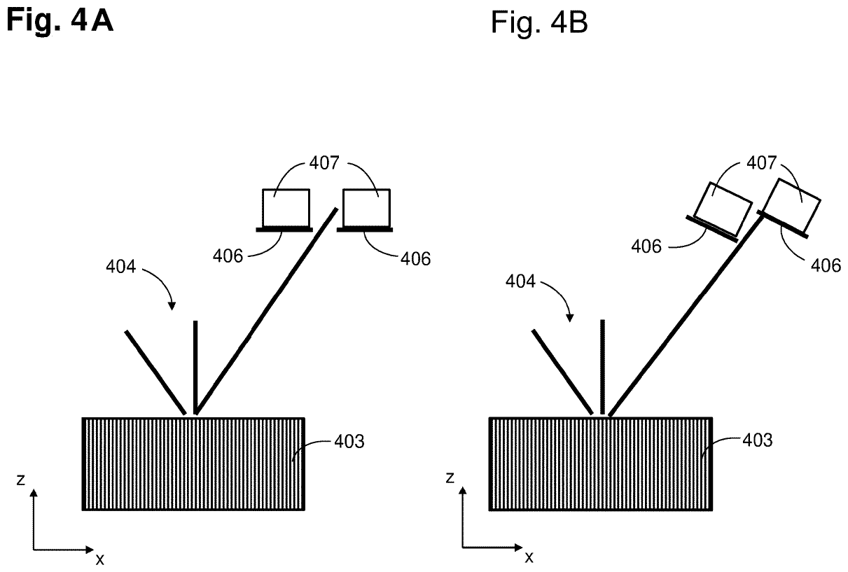

In further embodiments, the inventive tilting of the mirror substrates may also be implemented such that gaps or spacings situated between adjacent mirror substrates in the coating process are at least partially shadowed as a consequence of the tilting, i.e. are located in the shadow of the coating. This is illustrated in the schematic illustrations of FIGS. 4A-4B. Whereas, according to FIG. 4A, coating material 404 may reach and contaminate mechanical components 407 situated behind the mirror substrates 406 through gaps between adjacent mirror substrates, the mechanical components 407 are protected according to FIG. 4B as a consequence of suitable tilting and the shadowing brought about thereby.

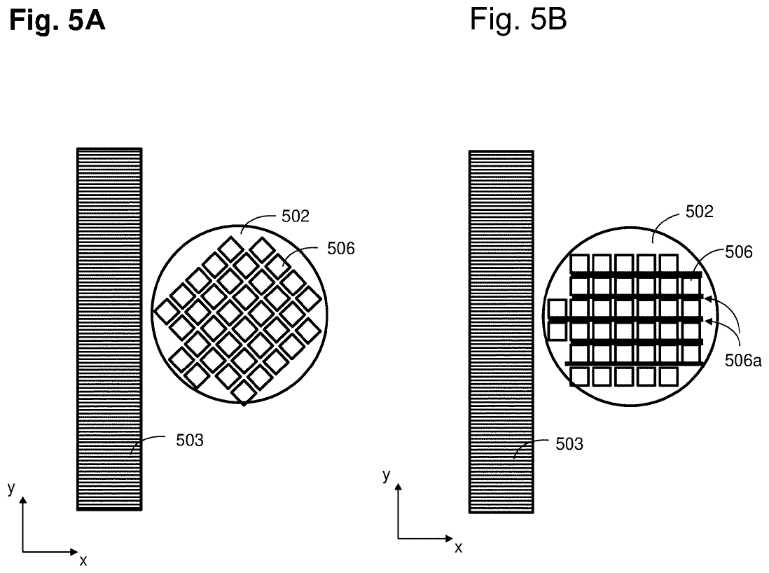

If need be, the additional use of a stop may narrow the vapor deposition angle distribution and/or the rate of coating material supply by the at least one target (“sputtering rate”) may be varied over time such that the amount of coating material reaching the respective mirror substrate from the target is reduced in respective phases of disadvantageous vapor deposition angles (within the meaning of the above-described possibility of contamination). FIGS. 5A-5B show (once again in a plan view of a coating mount 502 with mirror substrates 506 and a target 503) a schematic illustration of a scenario in which the above-described shadowing of gaps situated between adjacent mirror substrates 506 is successful (FIG. 5A) or not successful (FIG. 5B), depending on the rotational position of the coating mount 502. In this case, the rate of coating material supply from the at least one target (“sputtering rate”) is reduced in the rotational position of the coating mount 502 according to FIG. 5B (in which gaps 506a between the mirror substrates 506 are not shadowed) in order to avoid contamination of mechanical components situated behind the gaps with coating material.

In further embodiments, the trajectory of the coating mount may also be designed such that the mirror substrates are not situated perpendicular over the target at any point during the coating process, wherein a rotational movement in particular is optionally implemented about only a single (spin) axis of rotation.

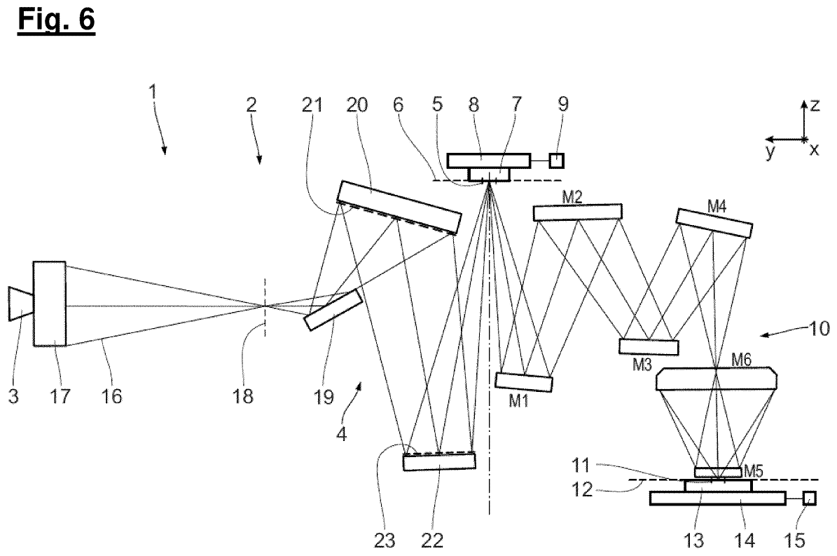

FIG. 6 schematically shows in meridional section the possible structure of a microlithographic projection exposure apparatus designed for operation in the EUV wavelength range.

According to FIG. 6, the projection exposure apparatus 1 comprises an illumination device 2 and a projection lens 10. One embodiment of the illumination device 2 of the projection exposure apparatus 1 has, in addition to a light or radiation source 3, an illumination optical unit 4 for illuminating an object field 5 in an object plane 6. In an alternative embodiment, the light source 3 may also be provided as a module separate from the rest of the illumination device. In this case, the illumination device does not comprise the light source 3.

A reticle 7 arranged in the object field 5 is exposed here. The reticle 7 is held by a reticle holder 8. The reticle holder 8 is displaceable in particular in a scanning direction using a reticle displacement drive 9. For explanation purposes, a Cartesian xyz-coordinate system is plotted in FIG. 6. The x-direction runs perpendicularly to and into the plane of the drawing. The y-direction runs horizontally, and the z-direction runs vertically. The scanning direction runs in the y-direction in FIG. 6. The z-direction runs perpendicularly to the object plane 6.

The projection lens 10 serves for imaging the object field 5 into an image field 11 in an image plane 12. A structure on the reticle 7 is imaged onto a light-sensitive layer of a wafer 13 arranged in the region of the image field 11 in the image plane 12. The wafer 13 is held by a wafer holder 14. The wafer holder 14 is displaceable in particular in the y-direction using a wafer displacement drive 15. The displacement, firstly, of the reticle 7 by the reticle displacement drive 9 and, secondly, the displacement of the wafer 13 by the wafer displacement drive 15 may be synchronized with one another.

The radiation source 3 is an EUV radiation source. The radiation source 3 in particular emits EUV radiation, which is also referred to below as used radiation or illumination radiation. In particular, the used radiation has a wavelength in the range of between 5 nm and 30 nm. The radiation source 3 may, for example, be a plasma source, a synchrotron-based radiation source or a free electron laser (FEL). The illumination radiation 16 emanating from the radiation source 3 is focused by a collector 17 and propagates through an intermediate focus in an intermediate focal plane 18 into the illumination optical unit 4. The illumination optical unit 4 comprises a deflection mirror 19 and, arranged downstream thereof in the beam path, a first facet mirror 20 (having schematically indicated facets 21) and a second facet mirror 22 (having schematically indicated facets 23). The facet mirrors 21, 22 may be produced e.g. using the inventive method or using an inventive coating apparatus.

The projection lens 10 comprises a plurality of mirrors Mi (i=1, 2, . . . ), which are consecutively numbered according to their arrangement in the beam path of the projection exposure apparatus 1. In the example illustrated in FIG. 6, the projection lens 10 comprises six mirrors M1 to M6. Alternatives with four, eight, ten, twelve, or any other number of mirrors Mi are likewise possible. The penultimate mirror M5 and the last mirror M6 each have a through-opening for the illumination radiation 16. The projection lens 10 is a doubly obscured optical unit. The projection lens 10 has an image-side numerical aperture that is greater than 0.5 and may also be greater than 0.6 and may be for example 0.7 or 0.75.

Even though the invention has been described on the basis of specific embodiments, numerous variations and alternative embodiments will be apparent to a person skilled in the art, for example through combination and/or exchange of features of individual embodiments. From the disclosure given, those skilled in the art will understand that such variations and alternative embodiments are also comprised by the present invention. The scope of the invention covers all such variations and alternatives that fall within the spirit and scope of the invention and extends to any and all equivalents to the disclosed and claimed structures and methods.

What is claimed is:

1. A method for producing a mirror arrangement having a plurality of mirror elements, comprising:
in a coating process performed in a coating apparatus, supplying coating material from at least one target to a plurality of mirror substrates for depositing respective layer systems on each of the mirror substrates; and
tilting each of the mirror substrates about a tilt angle set individually for each of the mirror substrates, for individually setting respective thickness profiles created in the coating process.

2. The method as claimed in claim 1, wherein said tilting is implemented such that a systematic coating error of the coating apparatus is at least partially corrected via the thickness profiles created for the plurality of mirror substrates.

3. The method as claimed in claim 1, wherein said tilting is implemented such that an adjustment error of the mirror substrates in the coating apparatus is at least partially corrected via the thickness profiles created for the plurality of mirror substrates.

4. The method as claimed in claim 1, wherein said tilting is implemented such that mutually differing thickness profiles are created for the plurality of mirror substrates.

5. The method as claimed in claim 1, wherein said tilting is implemented such that respective constant thickness profiles are created for the individual mirror substrates.

6. The method as claimed in claim 1, further comprising varying at least one further layer property in addition to the layer thickness profile, for modifying a mean deposition angle in the coating process.

7. The method as claimed in claim 6, wherein the at least one furter property comprises at least one of roughness, crystallinity or layer stress.

8. The method as claimed in claim 1, further comprising moving the mirror substrates along a predetermined trajectory relative to the target in the coating process.

9. The method as claimed in claim 8, wherein said tilting of the individual mirror substrates comprises varying said tilting for each of the mirror substrates.

10. The method as claimed in claim 9, wherein said varying is implemented such that said tilting of the respective mirror substrate is tilted in the direction of the target during the entire pass over the trajectory or said tilting of the respective mirror substrate is tilted away from the target during the entire pass over the trajectory.

11. The method as claimed in claim 1, further comprising rotating the mirror substrates during the coating process, and wherein said tilting is implemented based on respective rotation angle of this rotation.

12. The method as claimed in claim 1, wherein said tilting is implemented such gaps located between adjacent mirror substrates are at least partially shadowed in the coating process from said tilting.

13. The method as claimed in claim 1, wherein said supplying of the coating material by the at least one target is implemented with a time-varying rate.

14. The method as claimed in claim 1, wherein the mirror arrangement is configured for an operating wavelength of less than 30 nm.

15. The method as claimed in claim 13, wherein the mirror arrangement is configured for an operating wavelength of less than 15 nm.

16. A coating apparatus for producing a mirror arrangement, having:
a process chamber comprising:
at least one target configured and arranged to provide coating material;
a coating mount configured and arranged to hold a plurality of mirror substrates;
a first drive unit configured and arranged to perform a translational movement of the coating mount;
a second drive unit configured and arranged to perform a rotational movement of the coating mount; and
a third drive unit configured and arranged to individually set tilting of the mirror substrates during the coating process.
